(19) United States
(12) Patent Application Publication
(10) Pub. No.: US 2026/0063238 A1
(43) Pub. Date: Mar. 5, 2026

(54) VEHICLE MOTION CONTROL PLATFORMS

(71) Applicants: Sony Group Corporation, Tokyo (JP); Sony Pictures Entertainment Inc., Culver City, CA (US)

(72) Inventors: Jason Elbourne, Belleville (CA); Mahmoud Rahnama, Toronto (CA); David John McIntosh, North Vancouver (CA)

(21) Appl. No.: 18/821,567

(22) Filed: Aug. 30, 2024

(51) Int. Cl. F16M 11/12; B25J 9/00; G03B 15/07; G06F 30/15; H04N 5/222

(52) U.S. Cl. CPC F16M 11/12; B25J 9/0033; G06F 30/15; H04N 5/2224; G03B 15/07

(57) ABSTRACT

A virtual production apparatus, including: a motion control platform used for virtual production, the motion control platform integrated and controlled to enable synchronization with camera cranes, the driving simulators and virtual production stages, wherein the motion control platform is designed to increase gross moving load, increase available movement types, and lower a minimum height to enable loading of vehicles or objects onto the platform.

### BACKGROUND

### Field

The present disclosure relates to motion control platforms, and more specifically, to motion control platforms to enable synchronization with camera cranes, driving simulators, and virtual production stages.

### Background

In virtual production environment, a typical six degrees of freedom motion platform can simulate motions in six independent directions: surge (forward-backward), sway (left-right), heave (up-down), roll (tilt), pitch (nod), and yaw (turn). The platform may enable a realistic simulation of various motion scenarios. However, this type of platform may only provide a limited set of controls and may only be configured for certain types of vehicles.

Therefore, a different platform needs to be set up and configured for each different scenario. Also, this type of platform may be very bulky and hard to use. For example, installation of this type of platform may involve cranes and forklifts to move the vehicle/object to a height that is required and to mount it onto the platform. Thus, working at these heights is hard for setup crews and actors to access the vehicle. Further, although this type of platform may provide six degrees of freedom, its movement in certain directions may be limited. For example, a yaw rotation for the platform may be limited due to the position of the vehicle/object on the platform.

Accordingly, a need exists to improve the design and configuration of the platform.

### SUMMARY

The present disclosure describes motion control platforms to enable synchronization with camera cranes, driving simulators, and virtual production stages.

In one implementation, a virtual production apparatus is disclosed. The apparatus includes a motion control platform used for virtual production, the motion control platform integrated and controlled to enable synchronization with camera cranes, the driving simulators and virtual production stages, wherein the motion control platform is designed to increase gross moving load, increase available movement types, and lower a minimum height to enable loading of vehicles or objects onto the platform.

In another implementation, a system for virtual production is disclosed. The system includes camera cranes; driving simulators; virtual production stages; and a motion control platform used for virtual production, the motion control platform integrated and controlled to enable synchronization with the camera cranes, the driving simulators and the virtual production stages.

Other features and advantages should be apparent from the present description which illustrates, by way of example, aspects of the disclosure.

### BRIEF DESCRIPTION OF THE DRAWINGS

The details of the present disclosure, both as to its structure and operation, may be gleaned in part by study of the appended drawings, in which like reference numerals refer to like parts, and in which:

FIG. 1A is a top view of the motion control platform in accordance with one implementation of the present disclosure;

FIG. 1B is a front view of the motion control platform in accordance with one implementation of the present disclosure;

FIG. 1C is a side view of the motion control platform in accordance with one implementation of the present disclosure;

FIG. 1D is a bottom view of the motion control platform in accordance with one implementation of the present disclosure; and

FIG. 1E is an isometric view of the motion control platform in accordance with one implementation of the present disclosure.

### DETAILED DESCRIPTION

As described above, a need exists to improve the design and configuration to provide reusable and adaptable motion control platforms.

Certain implementations of the present disclosure provide for a reusable and adaptable motion control platform that can be integrated and controlled (e.g., using real-time 3-D creation tool such as Unreal Engine or other integration control software) to enable synchronization with camera cranes, driving simulators and virtual production stages (e.g., LED walls), individually and in combination. In one implementation, the platform is designed to increase gross moving load, available movement types (mainly in the yaw movement), and lower the minimum height to enable loading of vehicles/objects at a faster pace than existing technologies, as well as a safer height for setup crews and actors. After reading the descriptions below, it will become apparent how to implement the disclosure in various implementations and applications.

Although various implementations of the present disclosure will be described herein, it is understood that these implementations are presented by way of example only, and not limitation. As such, the detailed description of various implementations should not be construed to limit the scope or breadth of the present disclosure.

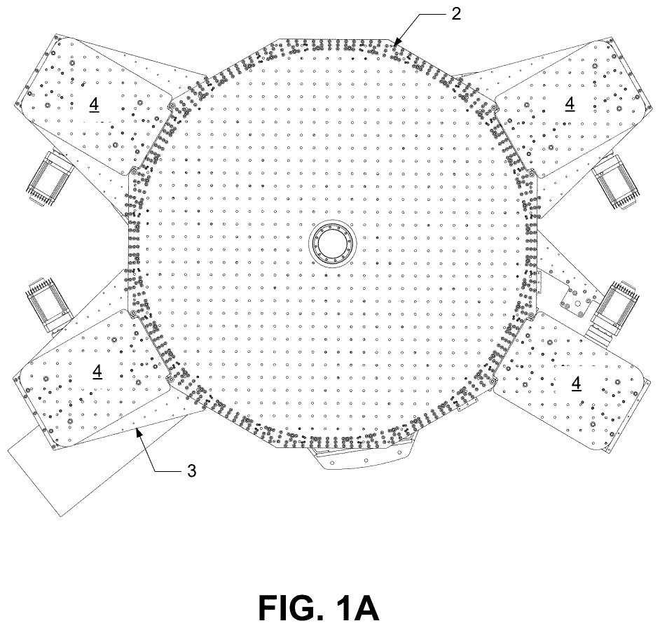

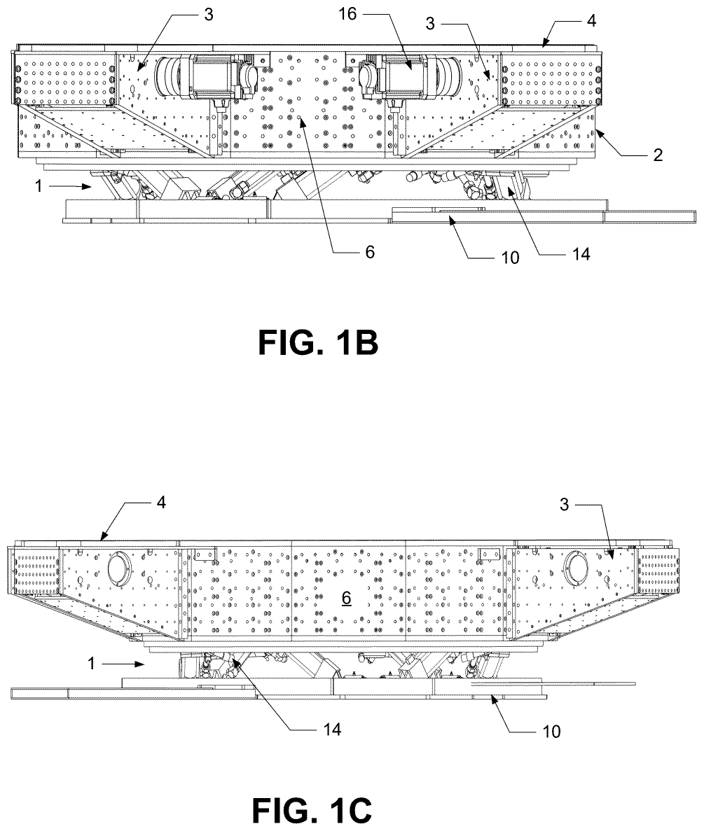

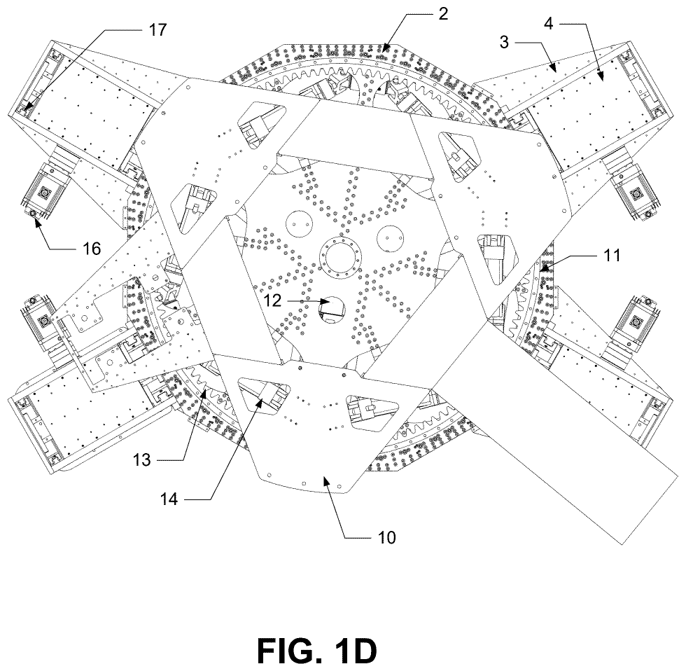

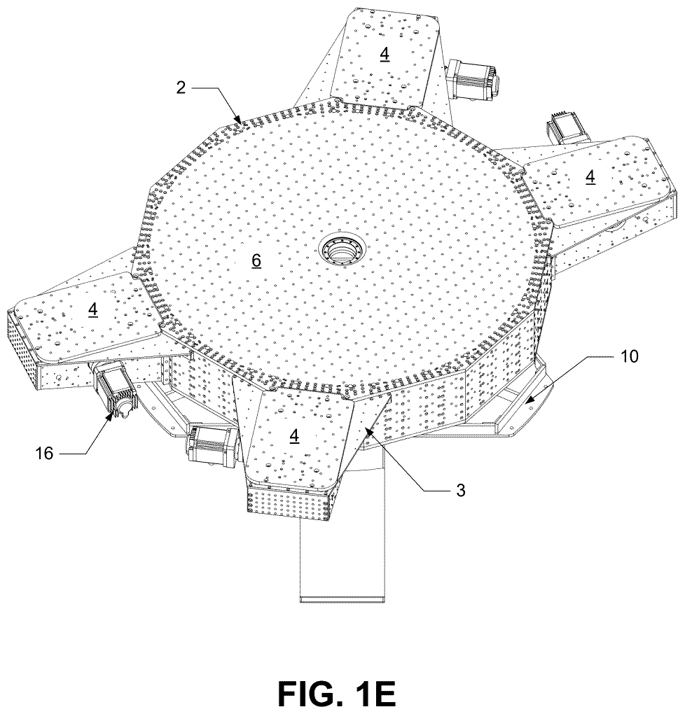

In one implementation, FIGS. 1A to 1E show a motion control platform 100 including a hydraulic base (1), a rotating upper platform (2), suspension control platforms (3) with paddles (4) branching from the rotating upper platform (2), wheel rollers (5), structural skirting (6), a hydraulic power plant (7), a control hub (8), a control center (9), a floor base (10), cam followers (11), hydraulic motors (12), alloy gears (13), hydraulic cylinders (14), hydraulic accumulators (15), servo motors (16), and guide rails (17).

FIG. 1A is a top view of the motion control platform 100 in accordance with one implementation of the present disclosure. The illustrated implementation of FIG. 1A highlights the upper platform (2), and the suspension control platforms (3) with the paddles (4) branching from the rotating upper platform (2).

In one implementation, the upper platform (2) is a rotating platform. In one implementation, the suspension control platforms (3) are configured as four removable platforms (with four paddles or appendages (4)) branching from the rotating upper platform (2). In one implementation, each paddle (4) includes approximately 4″ of travel (i.e., 4″±10%) to add vibration or motion to the motion control platform 100.

FIG. 1B is a front view of the motion control platform 100 in accordance with one implementation of the present disclosure. The illustrated implementation of FIG. 1B highlights the hydraulic base (1), the structural skirting (6), the floor base (10), the hydraulic cylinders (14), and the servo motors (16).

In one implementation, the hydraulic base (1) is configured as a Stewart platform having prismatic actuators to provide 6-degrees of freedom. In one implementation, the structural skirting (6) is configured to support “mod & rock n' roll” truss or any other fabricated structure to support filming equipment including rigid camera mounts, powered camera sliders, lighting rigs, special effects (SPFX) rigs (such as rain for windows) and deck extensions. In one implementation, the floor base (10) is configured as a steel floor base. In one implementation, the hydraulic cylinders (14) are configured as steel cylinders (e.g., 6 cylinders) with valving and sensors attached to the cylinders. In one implementation, the servo motors (16) are configured as steel, copper, or aluminum motors.

FIG. 1C is a side view of the motion control platform 100 in accordance with one implementation of the present disclosure. The illustrated implementation of FIG. 1C highlights the hydraulic base (1), the suspension control platforms (3) with the paddles (4), the floor base (10), and the hydraulic cylinders (14).

FIG. 1D is a bottom view of the motion control platform 100 in accordance with one implementation of the present disclosure. The illustrated implementation of FIG. 1D highlights the upper platform (2), the suspension control platforms (3) with the paddles (4), the floor base (10), the cam followers (11), the hydraulic motors (12), the alloy gears (13), the hydraulic cylinders (14), the servo motors (16), and the guide rails (17).

In one implementation, the cam followers (11) are configured as high-strength steel wheels. In one implementation, the hydraulic motors (12) are configured as steel motors for rotation (e.g., three motors). In one implementation, the alloy gears (13) are configured as heat-treated Chromium-based alloy gears for rotation. In one implementation, the guide rails (17) are configured as high-strength steel guide rails with bearings for suspension control platform with paddle.

FIG. 1E is an isometric view of the motion control platform 100 in accordance with one implementation of the present disclosure. The illustrated implementation of FIG. 1E highlights the upper platform (2), the suspension control platforms (3) with the paddles (4) branching from the rotating upper platform (2), the structural skirting (6), the floor base (10), and the servo motors (16).

In one implementation, the motion control platform 100 shown in FIGS. 1A to 1E also includes wheel rollers (5), a hydraulic power plant (7), a control hub (8), a control center (9), and hydraulic accumulators (15).

In one implementation, the wheel rollers (5) are configured as rollers with swivels to allow the vehicle wheels to rotate for the camera and the steering wheel to turn the tires. In one implementation, the hydraulic power plant (7) includes multiple electric meters powering multiple hydraulic pumps to supply and cool hydraulic fluid for the motion control platform 100. In one implementation, the control hub (8) is a location where motion controller and servo motor drives are housed. In one implementation, the control center (9) (including human-machine interface) is where the hand control of the platform 100 is located. In one implementation, the motion control platform 100 also includes aluminum hydraulic manifolds.

In one implementation, features provided for finishes for the motion control platform may include:
(a) Large upper plate of platform (e.g., dodecagon in geometry) painted with satin black enamel;
(b) Upper plates that contact the set piece of the paddles (e.g., 4 plates with satin black epoxy paint);
(c) All other aluminum to be black and red anodized;
(d) The steel floor base to be black satin epoxy paint; and
(e) All other hardware (nuts and bolts) to be black satin epoxy paint.

In one implementation, the dimensions are as follows:
(a) Weight is approximately 8,000 lbs (i.e., 8,00 lbs±10%); and
(b) Width 8′, Length 150″, and Height 28″.

In one implementation, the range of motion includes:
(a) Approximately 12.5°(i.e., 12.5°±10%) each direction for a small version of hydraulic cylinder;
(b) Unlimited range for top rotation;
(c) Suspension control platform with paddle: 4″ of travel; and
(d) Unlimited wheel roll and unlimited swivel.

In one implementation, the load capacity is approximately 8,000-10,000 lbs of deck load.

In one implementation, features provided for a control system may include:
(a) Human-machine interface used to manually control motion of the platform (Motion may be captured and saved);
(b) Custom digital twin application used to drive the motion of the platform to mimic a virtual vehicle driving over a virtual landscape:
(b1) digital twin application may send animation curve data in the form of frame translation/rotation data, properties, and commands to start and stop the motion;
(b2) digital twin application may send wheel movement data, when applicable, to the motion platform's suspension control and paddle system;
(c) Motion control platform may send current position data and log messages back to the digital twin integration application.

In one implementation, features provided for configuration for vehicles may include:
(a) Suspension control platforms with paddles which may be added to the upper shell of the motion control platform to configure mounting of multiple wheel configuration including vehicles with no wheels such as boats, aircraft fuselage and creature bucks.

In one implementation, features provided for configuration for production needs may include:
(a) Supporting mod & rock n' roll truss or any other fabricated structure connected to upper shell of the motion control platform to support filming equipment (e.g., rigid camera mounts, powered camera sliders, lighting rigs, special effects rigs (such as rain for windows) and deck extensions for set pieces.

In one implementation, features provided for hydraulic power plant may include:
(a) The hydraulic power plant may be packaged into a metal shipping container and positioned at an exterior location close to the building where the motion control platform is being operated.

In one implementation, features provided for moving the motion control platform may include:
(a) Lifting and moving the platform with a forklift at lift point(s);
(b) Disconnecting the upper shell of the platform from the base for easier moving and storage when needed; and
(c) Shipping the platform on a standard flatbed transport truck with the Hydraulic Power Plant container and an additional shipping container for all additional material and tools/parts.

In one implementation, features provided for the safety system may include:
(a) Having safety lighting indicating safe/warning/danger conditions for the platform's state during the operation of the motion control;
(b) Having a physical emergency stop trigger as well as a digital emergency stop trigger; and
(c) Requiring the platform operator to continuously press the dead-man button to keep the platform moving so that the platform stops immediately if the operator releases the button (i.e., the platform cannot move on its own and always requires human control).

In another implementation, other alternative designs of the motion control platform include:
(a) Using an electric power plant rather than a hydraulic power plant to change the load capacity;
(b) Changing the size and length of the hydraulic cylinders to increase the range of motion and platform minimum height;
(c) Changing the type and specification of materials (e.g., using the aluminum 6061T6); and
(d) Increasing or decreasing the number of removable suspension control platforms with the paddle.

In summary, the new features of the present disclosure include:
(a) Rotating upper platform to provide the ability to spin the top shell of the motion platform to infinite degrees;
(b) Lowering the minimum height of the motion platform with the ability to tilt toward floor, which allows a vehicle to simply drive onto the platform;
(c) Providing the ability to integrate into an ecosystem of motion controllers and motion-controlled equipment with a shaped interface;
(d) Providing the ability to reconfigure itself with minimal supporting tools and to support a wide range or vehicle configurations and wheelbases, including mounting of 4-wheel, 2-wheel and no-wheel vehicles/bucks;
(e) Providing the ability to combine in one platform of the motion control base for full vehicle movement with the suspension control platform with paddle to control unlimited wheel roll and unlimited swivel;
(f) Decreasing the overall volume size of the unit and increasing the gross moving load; and
(g) Providing a structural skirt to support mod & rock n' roll truss or any other fabricated structure to support filming equipment.

The advantages of the present disclosure include:
(a) Decreasing the minimum height from approximately 1,350 mm to 712 mm;
(b) Increasing the yaw rotation from ±12.0°to unlimited;
(C) Increasing the pitch angles from ±7.0°to ±12.0°;
(d) Increasing the roll angles from ±6.0°to ±12.0°;
(e) Increasing the load capacity from approximately 2000 kg to over 4000 kg (gross moving load);
(f) Providing added individual wheel bounce and rotation to full vehicle motion platform;
(g) Supporting mod & rock n' roll truss or any other fabricated structure to support filming equipment; and
(h) Integrating the control center into the digital twin of the production stage allowing communication and control in sync (Linear Timecode, genlock, and/or framelock) with a virtual production LED system, camera control system and driving simulator.

In a particular implementation, a virtual production apparatus is disclosed. The apparatus includes a motion control platform used for virtual production, the motion control platform integrated and controlled to enable synchronization with camera cranes, the driving simulators and virtual production stages, wherein the motion control platform is designed to increase gross moving load, increase available movement types, and lower a minimum height to enable loading of vehicles or objects onto the platform.

In one implementation, the motion control platform is integrated and controlled using a real-time 3-D creation tool. In one implementation, the virtual production stages include LED walls. In one implementation, the motion control platform includes at least one of: a hydraulic base; an upper platform; suspension control platforms with paddles branching from the upper platform; wheel rollers; structural skirting; a hydraulic power plant; a floor base; cam followers; hydraulic motors; alloy gears; hydraulic cylinders; hydraulic accumulators, servo motors; and guide rails. In one implementation, the upper platform is a rotating platform. In one implementation, the suspension control platforms are configured as four removable platforms branching from the upper platform. In one implementation, each paddle includes approximately 4″ of travel to add vibration or motion to the motion control platform. In one implementation, the hydraulic base is configured as a Stewart platform including prismatic actuators to provide 6-degrees of freedom. In one implementation, the structural skirting is configured to support mod & rock n' roll truss to support filming equipment including rigid camera mounts, powered camera sliders, lighting rigs, special effects (SPFX) rigs and deck extensions. In one implementation, the hydraulic cylinders are configured as steel cylinders with valving and sensors attached to the cylinders. In one implementation, the servo motors are configured as one of steel, copper, or aluminum motors. In one implementation, the cam followers are configured as high-strength steel wheels. In one implementation, the hydraulic motors are configured as steel motors for rotation. In one implementation, the alloy gears are configured as heat-treated Chromium-based alloy gears for rotation. In one implementation, the guide rails are configured as steel guide rails with bearings for the suspension control platform. In one implementation, the motion control platform further comprises at least one of wheel rollers, a hydraulic power plant, and hydraulic accumulators. In one implementation, the hydraulic power plant includes multiple electric meters powering multiple hydraulic pumps to supply and cool hydraulic fluid for the motion control platform.

In one implementation, the motion control platform further comprises a control center where hand control of the motion control platform is located.

In another particular implementation, a virtual production system is disclosed. The system includes camera cranes; driving simulators; virtual production stages; and a motion control platform used for virtual production, the motion control platform integrated and controlled to enable synchronization with the camera cranes, the driving simulators and the virtual production stages.

In one implementation, the motion control platform is designed to increase gross moving load, increase available movement types, and lower a minimum height to enable loading of vehicles or objects onto the platform.

All features of each of the above-discussed examples are not necessarily required in a particular implementation of the present disclosure. Further, it is to be understood that the description and drawings presented herein are representative of the subject matter which is broadly contemplated by the present disclosure. It is further understood that the scope of the present disclosure fully encompasses other implementations that may become obvious to those skilled in the art and that the scope of the present disclosure is accordingly limited by nothing other than the appended claims.

1. A virtual production apparatus, comprising:
a motion control platform used for virtual production,
the motion control platform integrated and controlled to enable synchronization with camera cranes, the driving simulators and virtual production stages,
wherein the motion control platform is designed to increase gross moving load, increase available movement types, and lower a minimum height to enable loading of vehicles or objects onto the platform.

2. The apparatus of claim 1, wherein the motion control platform is integrated and controlled using a real-time 3-D creation tool.

3. The apparatus of claim 1, wherein the virtual production stages include LED walls.

4. The apparatus of claim 1, wherein the motion control platform includes at least one of: a hydraulic base; an upper platform; suspension control platforms with paddles branching from the upper platform; wheel rollers; structural skirting; a hydraulic power plant; a floor base; cam followers; hydraulic motors; alloy gears; hydraulic cylinders; hydraulic accumulators, servo motors; and guide rails.

5. The apparatus of claim 4, wherein the upper platform is a rotating platform.

6. The apparatus of claim 4, wherein the suspension control platforms are configured as four removable platforms branching from the upper platform.

7. The apparatus of claim 4, wherein each paddle includes approximately 4″ of travel to add vibration or motion to the motion control platform.

8. The apparatus of claim 4, wherein the hydraulic base is configured as a Stewart platform including prismatic actuators to provide 6-degrees of freedom.

9. The apparatus of claim 4, wherein the structural skirting is configured to support mod & rock n' roll truss to support filming equipment including rigid camera mounts, powered camera sliders, lighting rigs, special effects (SPFX) rigs and deck extensions.

10. The apparatus of claim 4, wherein the hydraulic cylinders are configured as steel cylinders with valving and sensors attached to the cylinders.

11. The apparatus of claim 4, wherein the servo motors are configured as one of steel, copper, or aluminum motors.

12. The apparatus of claim 4, wherein the cam followers are configured as high-strength steel wheels.

13. The apparatus of claim 4, wherein the hydraulic motors are configured as steel motors for rotation.

14. The apparatus of claim 4, wherein the alloy gears are configured as heat-treated Chromium-based alloy gears for rotation.

15. The apparatus of claim 4, wherein the guide rails are configured as steel guide rails with bearings for the suspension control platform.

16. The apparatus of claim 1, wherein the motion control platform further comprises at least one of wheel rollers, a hydraulic power plant, and hydraulic accumulators.

17. The apparatus of claim 1, wherein the hydraulic power plant includes multiple electric meters powering multiple hydraulic pumps to supply and cool hydraulic fluid for the motion control platform.

18. The apparatus of claim 1, wherein the motion control platform further comprises a control center where hand control of the motion control platform is located.

19. A virtual production system, comprising:
camera cranes;
driving simulators;
virtual production stages; and
a motion control platform used for virtual production,
the motion control platform integrated and controlled to enable synchronization with the camera cranes, the driving simulators and the virtual production stages.

20. The system of claim 19, wherein the motion control platform is designed to increase gross moving load, increase available movement types, and lower a minimum height to enable loading of vehicles or objects onto the platform.
